(19) United States
(12) Patent Application Publication
(10) Pub. No.: US 2007/0090344 A1
(43) Pub. Date: Apr. 26, 2007

(54) Multi-stable molecular device

(75) Inventors: R. Stanley Williams, Portola Valley, CA (US); Philip John Kuekes, Menlo Park, CA (US); Alexandre Bratkovski, Mountain View, CA (US)

Correspondence Address: SCHWEGMAN, LUNDBERG, WOESSNER & KLUTH, P.A., P.O. BOX 2938, MINNEAPOLIS, MN, 55402, US

(73) Assignee: Hewlett-Packard Development Company, L.P.

(21) Appl. No.: 11/256,856

(22) Filed: Oct. 24, 2005

(51) Int. Cl. H01L 29/08

(52) U.S. Cl. 257/40

(57) ABSTRACT

In accordance with the present invention, a molecular device is provided that can act as a finite state machine, such as a logic device or a memory device. The molecular device includes operating molecules having two or more rotors. Each rotor has an electric dipole moment and multiple discrete rotor configurational states. A rotor can be any suitable and effective group that has an electric dipole moment and multiple discrete rotor configurational states. An individual rotor configurational state can be substantially or completely independent of the rotor configurational states of other rotors. The rotor configurational states can be binary. The molecular configurational state of a multi-stable molecule of a device can be ascertained by measuring conductance.

### BACKGROUND

The area of molecular scale electronics is a relatively new but rapidly growing field. Collier et al. (Science, 1999, 285, 391-394) and Chen et al. (Appl. Phys. Lett., 2003, 82, 1610-1612) developed electronic switches using a monolayer film of molecules called rotaxanes that were trapped between two metal electrodes and caused them to switch from an ON state to an OFF state by the application of a positive bias voltage across the molecules. The ON and OFF states differed in resistivity by about a factor of 100 to 10,000 because of a change in the rate of tunneling through the molecules and/or electrodes caused by oxidizing the molecules and/or electrodes with an applied voltage.

Rotaxanes require an oxidation or reduction to occur before the switch can be toggled on or off. This requires the expenditure of a significant amount of energy to toggle the switch. Additionally, the large and complex nature of rotaxane molecules and related compounds potentially makes the switching times of the molecules relatively slow.

### BRIEF DESCRIPTION OF THE DRAWINGS

FIG. 1a is a schematic representation according to an exemplary embodiment, of two crossed wires with at least one multi-stable molecule at the intersection of the two wires (electrodes) according to an example embodiment;

FIG. 1b is a perspective elevational view, depicting an example embodiment shown in FIG. 1a;

FIG. 2 is ball-and-stick drawing that depicts a molecular device according to an example embodiment, which has been designed with rotors appended perpendicular to the orientation or current-carrying axis of the entire molecule, wherein the top structure depicts a device with a rotor in one stable state and the bottom structure depicts the same device with that rotor in a second stable state according to an exemplary embodiment;

FIG. 3 is a continuation of FIG. 2, wherein the device on the bottom of FIG. 2 is illustrated at the top of FIG. 3, and the second rotor in the top structure is shown in its second stable state in the bottom structure, resulting in a third overall state;

FIGS. 4a-4c, on coordinates of current and voltage, are plots depicting a generic hysteresis loop for one rotor of the molecule device illustrated in FIGS. 2 and 3, wherein FIG. 4a depicts the I-V characteristic in one stable orientation with respect to the rotor, FIG. 4b depicts the I-V characteristic when the rotor is flipped to the second stable state, and FIG. 4c depicts the full hysteresis loop according to an example embodiment; and

FIG. 5 is a schematic representation of a two-dimensional array of switches depicting a 6×6 crossbar switch according to an example embodiment.

### DETAILED DESCRIPTION

In accordance with an example embodiment, a finite state machine is provided that has a plurality of multi-stable rotor-stator molecules. Each multi-stable molecule can have two or more rotors on each stator. At least one stator is in electrical contact with two electrodes to form a junction. Each rotor has an electric dipole moment. One or more of the multi-stable molecules have a first rotor having multiple discrete rotor configurational states and a second rotor having multiple discrete rotor configurational states either substantially or completely independent of the rotor configurational states of the first rotor.

The multi-stable molecules can be designed to have an hysteresis among molecular configurational states, wherein a sequence of distinct electric fields can be applied to set specific rotor configurational states such that when measured, the conductance of an electronic state associated with the specific molecular configurational state is the answer to a computation. The rotors of the finite state machine each independently have at least one energetic barrier to rotation which is greater than the thermal energy associated with the operating temperature of the finite state machine. The energetic barrier to rotation of the rotors can be any suitable and effective barrier to rotation, such as, e.g., hydrogen bonding, Van der Waals forces, or steric interactions.

Current can be passed through the electrodes that are in contact with a multi-stable molecule substantially along its longitudinal axis. The molecular configurational state of the multi-state molecule can be ascertained by passing current through the electrodes and measuring the conductance. The molecular configurational state of the multi-state molecules can be changed (i.e., a rotor can be rotated) by applying an electric field to said multi-state molecules through programming electrodes that are in physical, or alternatively electrical, contact with said multi-state molecules.

The finite state machine can operate as a memory device to store information in higher than binary fashion. The multiple discrete rotor configurational states of each rotor can be binary, tertiary, or quaternary. The multi-stable molecule can be designed to provide a desired truth table and therefore can be part of a logic device. The finite state machine can have two or more rotors that are independently C(═Y)Z; wherein Y is independently O; NR; or S; Z is independently R; N(R)(R′); OR; S(O)ₙR wherein n is 0, 1, or 2; CHR—NHR; CHR—OR; CHR—S(O)ₙR; CHR-halogen; NR—NHR; NR—OR; and NR—S(O)ₙR; and R and R′ are each independently H, alkyl, thioalkyl, cycloalkyl, aryl, heteroaryl, or heterocycle.

In accordance with an embodiment, a molecule is provided that has a first rotor having multiple discrete rotor configurational states, and a second rotor having multiple discrete rotor configurational states independent of the rotor configurational states of the first rotor. The rotor can be any suitable and effective group such as, e.g., an amide, an ester, a carboxylic acid, or substituted variations thereof. The multiple discrete rotor configurational states can be binary. The molecule can act as a logic device or a memory device that stores information in higher than binary fashion, e.g., instead of simply a 0 or 1, information can be stored as digits such as 0, 1, 2, 3, 4, or higher digits, thus greatly improving the amount of information that can be stored per unit circuit area.

In accordance with an embodiment, nanometer-scale reversible electronic switches are provided that can be assembled to make circuits that provide memory, logic, and communications functions. The electronic switches, for example, a crossed-wire device, can comprise a pair of crossed wires that form a junction where one wire crosses another, typically at an angle other than zero degrees, and at least one connector species connecting the pair of crossed wires in the junction. The junction has a functional dimension in nanometers. The connector species comprises a multi-stable molecule, an example of which is represented in Formula I: 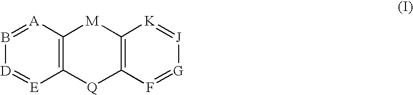
wherein

A, B, D, E, F, G, J, and K, are each independently C—X; C—H; C—R; C—N(R)(R′); N; C-halogen; C—OR; C—SR; C(═O)N(R)(R′); C(═O)OR; or C—(═O)SR;

M and Q are each independently C(R)(X); N—X; P(O)ₙX; boron-X; CH₂; CHR; CH(halogen); C(halogen)₂; CHOR; CO; —CH═CH—; —CH₂—CH₂—; C═C(R)(R′); S(O)ₙ; O; NR; or N—COR;

X is independently hydrogen or C(═Y)Z;

Y is independently O; NR; or S;

Z is independently R; N(R)(R′); OR; S(O)ₙR; CHR—NHR; CHR—OR; CHR—S(O)ₙR; CHR-halogen; NR—NHR; NR—OR; or NR—S(O)ₙR;

R and R′ are each independently H, alkyl, thioalkyl, cycloalkyl, aryl, heteroaryl, or heterocycle; and

n is 0-2;

provided at least two of A, B, D, E, F, G, J, K, M, and Q are X, wherein X is independently C(═Y)Z; and

provided at least two of A, B, D, E, F, G, J, K, M, and Q are independently C—(Yₘ—(CH₂)ₚ)_{q}—SH,

wherein each Y is independently O, NH, or S;

m is 0 or 1;

p is 0-12; and

q is 0-2.

In accordance with an embodiment, a method of fabricating an electronic device is described, wherein a pair of electrodes that form a junction is prepared. At the junction is at least one connector species connecting the pair of electrodes. The junction can contain one or more multi-stable molecules having a functional dimension in nanometers. The method includes (a) forming said first wire, (b) depositing said at least one connector species over at least a portion of said first wire, and (c) forming said second wire over said first wire so as to form said junction, wherein said at least one connector species comprises a multi-stable molecule, such as that represented by Formula I. A system including a multi-stable molecule, such as that represented by Formula I can also be prepared.

In accordance with an embodiment, a method of operating a molecular device is described, said method comprising biasing both wires at least once with a first voltage sufficient to cause said connector species to switch its state, wherein said at least one connector species comprises a multi-stable molecule such as, for example, a molecule of Formula I.

In accordance with an embodiment, a device can be prepared, wherein a pair of electrodes forms a junction where one electrode crosses another at an angle typically other than zero degrees. At least one connector species connects the pair of electrodes at a junction, where the junction has a functional dimension in nanometers, and wherein said at least one connector species comprises a multi-stable molecule such as, for example, a molecule of Formula I.

A device of an embodiment comprises a multi-stable molecule with multiple electronic states determined by relative configurations of the molecular components that have discrete electronic properties to be used for logic operations. Novel logic techniques, such as 4, 8, or higher state operations, may be performed, depending on the number of stable electronic states in the molecules that join the electrodes. One embodiment makes use of molecules with three or more stable internal electronic states, for which certain states have distinguishable electronic properties, such as resistance. The multi-stable molecules evidence high switching speeds, and are essentially stable against switching caused by thermal fluctuations of the operating device.

Definitions

As used herein, the term “rotor configurational state” refers to the orientation of a rotor with respect to the stator to which it is attached. A “molecular configurational state” refers to the set of the orientations of all the rotors on a particular stator. Each rotor can have at least two rotor configurational states, which are separated by an energy barrier.

As used herein, the term “electronic state” refers to the electronic characteristics of a multi-stable molecule as a result of its overall (molecular) configurational state. The electrical conductivity of an individual rotor-stator is determined by its overall configurational state. The electronic state of the molecules as a whole thus depends upon the configuration of its set of rotors.

As used herein, the term “electrode” refers to a conductor or semiconductor that is in physical contact with the stator portion of a multi-stable molecule. By passing current though electrodes, the electronic state of a multi-stable molecule can be ‘read’, for example, by measuring its conductance. Additionally, programming electrodes can be in physical or electrical contact with the stator of a multi-stable molecule, and such electrodes can be used to change the molecular configurational state of the molecule by forcing one or more rotors to rotate in order to align with an electric field placed across the molecule. The rotor configurational state of a rotor can be changed by applying an electric field substantially along a longitudinal axis of a multi-stable molecule. The electrodes used to read the molecular configurational state of a molecule (e.g., by measuring conductance) can be the same electrodes or different electrodes as those used to program the molecular configurational state of a molecule.

As used herein, the term “finite state machine” refers to any device that stores the status of a datum at a given time and can operate on input to change the status and/or cause an action or output to take place for any given change. A finite state machine can include an initial state or record of stored data, a set of possible input events, a set of new states that may result from the input, or a set of possible actions or output events that result from a new state. A finite state machine is one that has a limited or finite number of possible states. A finite state machine can be used both as a development tool for approaching and solving problems and as a formal way of describing the solution for later developers and system maintainers. There are a number of ways to illustrate a state machine, for example, as a truth table. A finite state machine can be a model of computation that has of a set of states, a start state, an input alphabet, and a transition function that can map input symbols and current states to a next state. Computation can begin in the start state with an input string. The finite state machine can change to new states depending on the transition function. There are many possible variants of the finite state machine. For instance, various aspects of the finite state machines include machines having actions (outputs) associated with transitions (Mealy machine) or states (Moore machine), multiple start states, transitions conditioned on no input symbol (a null) or more than one transition for a given symbol and state (nondeterministic finite state machine), and one or more states designated as accepting states (recognizer).

As used herein, the term “junction” refers to a multi-stable molecule between two electrodes, which results in the formation of a switch. The switch can be created wherever two electrodes contact each other at an angle typically other than zero degrees, because either one or both electrodes is coated or functionalized with a multi-stable molecule. A multi-stable molecule thus forms a junction between the two electrodes.

The term “self-assembled” as used herein refers to a system that naturally adopts a particular geometric pattern because of the identity of the components of the system; the system achieves at least a local minimum in its energy by adopting this configuration.

The term “singly configurable” refers to a switch that can change its state only once via an irreversible process such as an oxidation or reduction reaction; such a switch can be the basis of a programmable read-only memory (PROM), for example.

The term “reconfigurable” refers to a switch that can change its state multiple times via a reversible process such a change in the special conformation of a dipolar molecular component; in other words, the switch can be opened and closed multiple times, such as the memory bits in a random access memory (RAM).

The term “multi-stable” as applied to a molecule or a portion of a molecule refers to having more than two relatively low energy states separated by an energy (or activation) barrier. The molecule may be either irreversibly switched from one state to another (singly configurable) or reversibly switched from one state to one or more others (reconfigurable). The multi-stable molecules have three or more relatively low energy electronic states separated by energy (activation) barriers. The different electronic energy states are achieved by changing rotor configurational states. The barriers to rotation of the rotors can be the result of any suitable force (i.e., a holding or locking mechanism) that prevents a rotor from freely rotating in the absence of an electric field of sufficient strength. Such barriers include, for example, resistance to rotation from hydrogen bonding, Van der Waals forces, steric interactions, or any combination of such forces.

Micron-scale dimensions refers to dimensions that range from about 1 micrometer to about a few hundred micrometers in size.

Sub-micron scale dimensions refers to dimensions that range from about 1 micrometer down to about 0.05 micrometers.

Nanometer scale dimensions refers to dimensions that range from about 0.1 nanometers to about 50 nanometers (0.05 micrometers).

Micron-scale and submicron-scale wires refer to rod or ribbon-shaped conductors or semiconductors with widths or diameters having the dimensions of about 0.1 to about 10 micrometers, heights that can range from a few tens of nanometers to about one micrometer, and lengths of several micrometers up to a few centimeters.

The term “alkyl” refers to a monoradical branched or unbranched hydrocarbon chain having from 1 to about 40 carbon atoms, typically having 1 to about 10 carbon atoms. This term can be exemplified by groups such as methyl, ethyl, n-propyl, iso-propyl, n-butyl, iso-butyl, sec-butyl, tert-butyl, n-hexyl, n-decyl, tetradecyl, and substituted and/or unsaturated versions thereof. Alkyl groups can be optionally substituted and optionally partially unsaturated.

The alkyl can optionally be substituted with one or more alkoxy, halo, haloalkyl, hydroxy, hydroxyalkyl, aryl, heteroaryl, heterocycle, cycloalkyl, alkanoyl, alkoxycarbonyl, amino, alkylamino, acylamino, nitro, trifluoromethyl, trifluoromethoxy, carboxy, carboxyalkyl, keto, thioxo, thio, alkylthio, alkylsulfinyl, alkylsulfonyl and cyano. Alkyl groups can also be optionally interrupted on the carbon chain with one or more heteroatoms, including one or more of, e.g., oxygen, nitrogen, sulfur, and/or silicon.

The term “alkylene” refers to a diradical branched or unbranched saturated hydrocarbon chain preferably having from 1 to about 40 carbon atoms, typically having 1 to about 10 carbon atoms. This term is exemplified by groups such as methylene, ethylene, n-propylene, iso-propylene, n-butylene, iso-butylene, sec-butylene, n-hexylene, n-decylene, tetradecylene, and substituted and/or partially unsaturated versions thereof.

The alkylene can optionally be substituted with one or more alkoxy, halo, haloalkyl, hydroxy, hydroxyalkyl, aryl, heteroaryl, heterocycle, cycloalkyl, alkanoyl, alkoxycarbonyl, amino, alkylamino, acylamino, nitro, trifluoromethyl, trifluoromethoxy, carboxy, carboxyalkyl, keto, thioxo, alkylthio, alkylsulfinyl, alkylsulfonyl and cyano.

The term refers “aryl” refers to an unsaturated aromatic carbocyclic group of from 6 to about 20 carbon atoms having a single ring (e.g., phenyl) or multiple condensed (fused) rings, wherein at least one ring is aromatic (e.g., naphthyl, dihydrophenanthrenyl, fluorenyl, or anthryl).

An aryl group can optionally be substituted with one or more alkyl, alkoxy, halo, haloalkyl, hydroxy, hydroxyalkyl, heteroaryl, heterocycle, cycloalkyl, alkanoyl, alkoxycarbonyl, amino, alkylamino, acylamino, nitro, trifluoromethyl, trifluoromethoxy, carboxy, carboxyalkyl, keto, thioxo, alkylthio, alkylsulfinyl, alkylsulfonyl and cyano.

The term “cycloalkyl” refers to cyclic alkyl groups of from 3 to about 20 carbon atoms having a single cyclic ring or multiple condensed rings. Such cycloalkyl groups include, by way of example, single ring structures such as cyclopropyl, cyclobutyl, cyclopentyl, cyclohexyl, cyclooctyl, and the like, or multiple ring structures such as adamantanyl, and the like. Cycloalkyl groups can be optionally partially unsaturated.

The cycloalkyl can optionally be substituted with one or more alkyl, alkoxy, halo, haloalkyl, hydroxy, hydroxyalkyl, aryl, heteroaryl, heterocycle, alkanoyl, alkoxycarbonyl, amino, alkylamino, acylamino, nitro, trifluoromethyl, trifluoromethoxy, carboxy, carboxyalkyl, keto, thioxo, alkylthio, alkylsulfinyl, alkylsulfonyl and cyano.

The term “halo” refers to fluoro, chloro, bromo, and iodo. Similarly, the term “halogen” refers to fluorine, chlorine, bromine, and iodine.

“Haloalkyl” refers to alkyl as defined herein substituted by 1-4 halo groups as defined herein, which may be the same or different. Representative haloalkyl groups include, by way of example, trifluoromethyl, 3-fluorododecyl, 12,12,12-trifluorododecyl, 2-bromooctyl, 3-bromo-6-chloroheptyl, and the like.

The term “heteroaryl” is defined herein as a monocyclic, bicyclic, or tricyclic ring system containing one, two, or three aromatic rings and containing at least one nitrogen, oxygen, or sulfur atom in an aromatic ring, and that can be unsubstituted or substituted, for example, with one or more, and in particular one to three, substituents, like halo, alkyl, hydroxy, hydroxyalkyl, alkoxy, alkoxyalkyl, haloalkyl, nitro, amino, alkylamino, acylamino, alkylthio, alkylsulfinyl, and alkylsulfonyl. Examples of heteroaryl groups include, but are not limited to, 2H-pyrrolyl, 3H-indolyl, 4H-quinolizinyl, 4H-carbazolyl, acridinyl, benzo[b]thienyl, benzothiazolyl, β-carbolinyl, carbazolyl, chromenyl, cinnamolinyl, dibenzo[b,d]furanyl, furazanyl, furyl, imidazolyl, imidizolyl, indazolyl, indolisinyl, indolyl, isobenzofuranyl, isoindolyl, isoquinolyl, isothiazolyl, isoxazolyl, naphthyridinyl, naptho[2,3-b], oxazolyl, perimidinyl, phenanthridinyl, phenanthrolinyl, phenarsazinyl, phenazinyl, phenothiazinyl, phenoxathinyl, phenoxazinyl, phthalazinyl, pteridinyl, purinyl, pyranyl, pyrazinyl, pyrazolyl, pyridazinyl, pyridyl, pyrimidinyl, pyrimidinyl, pyrrolyl, quinazolinyl, quinolyl, quinoxalinyl, thiadiazolyl, thianthrenyl, thiazolyl, thienyl, triazolyl, and xanthenyl. In one embodiment the term “heteroaryl” denotes a monocyclic aromatic ring containing five or six ring atoms containing carbon and 1, 2, 3, or 4 heteroatoms independently selected from the group non-peroxide oxygen, sulfur, and N(Z′) wherein Z′ is absent or is H, O, alkyl, phenyl or benzyl. In another embodiment heteroaryl denotes an ortho-fused bicyclic heterocycle of about eight to ten ring atoms derived therefrom, particularly a benz-derivative or one derived by fusing a propylene, or tetramethylene diradical thereto.

The heteroaryl can optionally be substituted with one or more alkyl, alkoxy, halo, haloalkyl, hydroxy, hydroxyalkyl, aryl, heterocycle, cycloalkyl, alkanoyl, alkoxycarbonyl, amino, alkylamino, acylamino, nitro, trifluoromethyl, trifluoromethoxy, carboxy, carboxyalkyl, keto, thioxo, alkylthio, alkylsulfinyl, alkylsulfonyl and cyano.

The term “heterocycle” refers to a saturated or partially unsaturated ring system, containing at least one heteroatom selected from the group oxygen, nitrogen, and sulfur, and optionally substituted with alkyl or C(═O)OR^{b}, wherein R^{b} is hydrogen, alkyl, cycloalkyl, aryl, heterocycyl, or heteroaryl. Typically heterocycle is a monocyclic, bicyclic, or tricyclic group containing one or more heteroatoms selected from the group oxygen, nitrogen, and sulfur. A heterocycle group also can contain an oxo group (═O) attached to the ring. Non-limiting examples of heterocycle groups include 1,3-dihydrobenzofuran, 1,3-dioxolane, 1,4-dioxane, 1,4-dithiane, 2H-pyran, 2-pyrazoline, 4H-pyran, chromanyl, imidazolidinyl, imidazolinyl, indolinyl, isochromanyl, isoindolinyl, morpholine, piperazinyl, piperidine, piperidyl, pyrazolidine, pyrazolidinyl, pyrazolinyl, pyrrolidine, pyrroline, quinuclidine, and thiomorpholine.

The heterocycle can optionally be substituted with one or more alkyl, alkoxy, halo, haloalkyl, hydroxy, hydroxyalkyl, aryl, heteroaryl, cycloalkyl, alkanoyl, alkoxycarbonyl, amino, alkylamino, acylamino, nitro, trifluoromethyl, trifluoromethoxy, carboxy, carboxyalkyl, keto, thioxo, alkylthio, alkylsulfinyl, alkylsulfonyl and cyano.

Examples of nitrogen heterocycles and heteroaryls include, but are not limited to, pyrrole, imidazole, pyrazole, pyridine, pyrazine, pyrimidine, pyridazine, indolizine, isoindole, indole, indazole, purine, quinolizine, isoquinoline, quinoline, phthalazine, naphthylpyridine, quinoxaline, quinazoline, cinnoline, pteridine, carbazole, carboline, phenanthridine, acridine, phenanthroline, isothiazole, phenazine, isoxazole, phenoxazine, phenothiazine, imidazolidine, imidazoline, piperidine, piperazine, indoline, morpholino, piperidinyl, tetrahydrofuranyl, and the like as well as N-alkoxy-nitrogen containing heterocycles.

“Substituted” is intended to indicate that one or more hydrogens on the atom indicated in the expression using “substituted” is replaced with a selection from the indicated group(s), provided that the indicated atom's normal valence is not exceeded, and that the substitution results in a stable compound. Suitable indicated groups include, e.g., alkyl, alkoxy, halo, haloalkyl, hydroxy, hydroxyalkyl, aryl, heteroaryl, heterocycle, cycloalkyl, alkanoyl, alkoxycarbonyl, amino, alkylamino, acylamino, nitro, trifluoromethyl, trifluoromethoxy, carboxy, carboxyalkyl, keto, thioxo, alkylthio, alkylsulfinyl, alkylsulfonyl and cyano. When a substituent is keto (i.e., ═O) or thioxo (i.e., ═S) group, then 2 hydrogens on the atom are replaced by the oxygen or sulfur.

As to any of the above groups, which contain one or more substituents, it is understood, of course, that such groups do not contain any substitution or substitution patterns which are sterically impractical and/or synthetically non-feasible. In addition, the compounds in various embodiments include all stereochemical isomers arising from the substitution of these compounds.

Molecular Devices

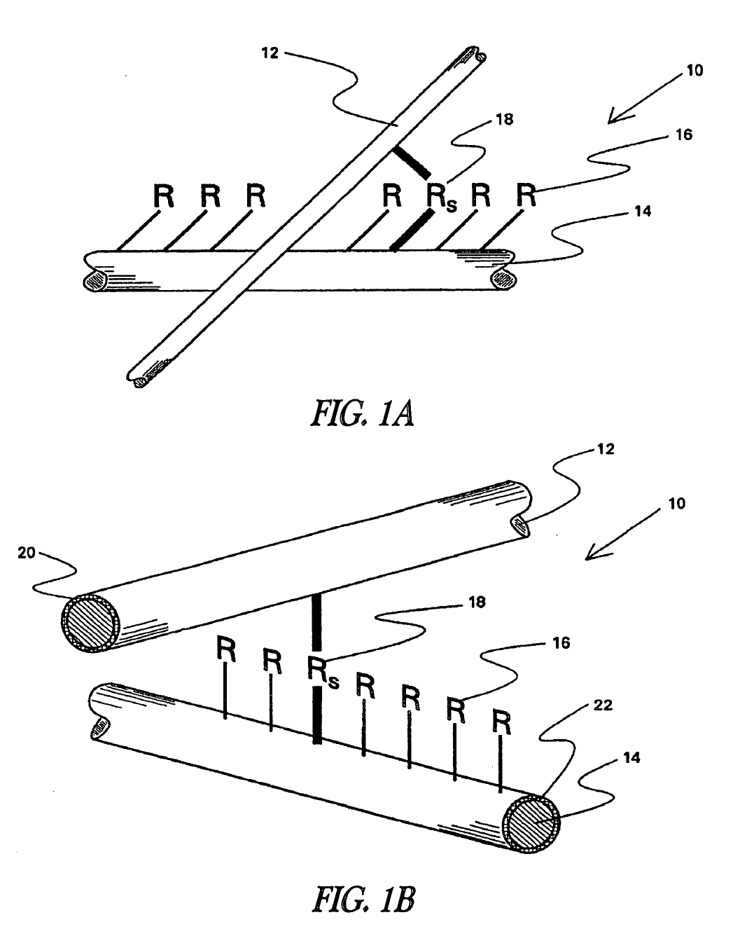

Features of a device according to an embodiment are shown in FIGS. 1a and 1b. A crossed wire switch 10 comprises two wires 12, 14, each either a metal or semiconductor wire, that can be, for example, crossed at a non-zero angle. In between the wires is a layer of molecules 16, denoted R in FIGS. 1a and 1b. The molecules 18 (denoted Rₛ) that are sandwiched at the intersection by the two wires 12, 14 are identified as switch molecules, also interchangeable referred to herein as junctions.

Each switch molecule has two or more rotor species appended to a larger, typically but not necessarily aromatic, base structure referred to as a stator. Stators can have completely or only partially conjugated chemical bonds. At least a portion of each stator is an electrical conductor. The stators can serve at least two functions. First, the stator can serve as a substantially rigid backbone to which the rotors are attached. The backbone can provide a steric barrier or other barriers to the rotation of its rotors. Second, the stator can serve an electrical conductance function. The segment of the rotor-stator molecule to which a rotor is attached can be a conjugated moiety, such as an aromatic ring of a compound of formula I, or the segment can be unconjugated, and thus less conductive or non-conductive. In certain embodiments, rotors will positioned at varying distances from one or more conductive portions of a multi-stable molecule. The rotor configurational states of certain rotors can affect the conductivity of the molecule to a different magnitude than the rotor configurational states of other rotors, depending on their location on the molecule relative to the conductive portion of the stator.

The rotor species possess significant intrinsic electric dipole moments, such that when an appropriate voltage is applied across the wires, the rotor rotates by an angle sufficient to switch the rotor configurational state of the molecule, changing the electronic state and thus the molecule's conductance. A sufficient angle can be approximately 60°, approximately 120°, approximately 180°, or any other suitable angle for switching the electronic state of the molecule.

The dipole moments of the rotors will tend to align parallel to the external field exerted on the molecule. If the initial direction of a particular rotor's dipole is opposite to that of the applied field, then the rotors will be forced to rotate with respect to the stator and switch to a second stable state at some threshold bias voltage. Switching changes the conformation of the rotors (the rotor configurational state), and thus changes the overall charge distribution of the junction (the molecular electronic state). These changes affect the effective tunneling distance or the tunneling barrier height between the two electrodes, thereby exponentially altering the rate of charge transport across the electrode junction, and serve as the basis for a switch.

Molecular switching components can arise from any variation of a molecule of Formula I, depending on the desired properties of the device. The key requirement of the multi-state molecule is that, when it is sandwiched between two wires, it may be spatially modified (i.e. a rotor is rotated to a different local energy minimum) by applying a voltage across the wires. When the junction rotors are so modified, the net effect is that the tunneling barrier between the two wires is modified, and the rate of current flow is changed. This forms the basis of a switch that can, in turn, be used for memory, logic operations, and communication and signal routing networks.

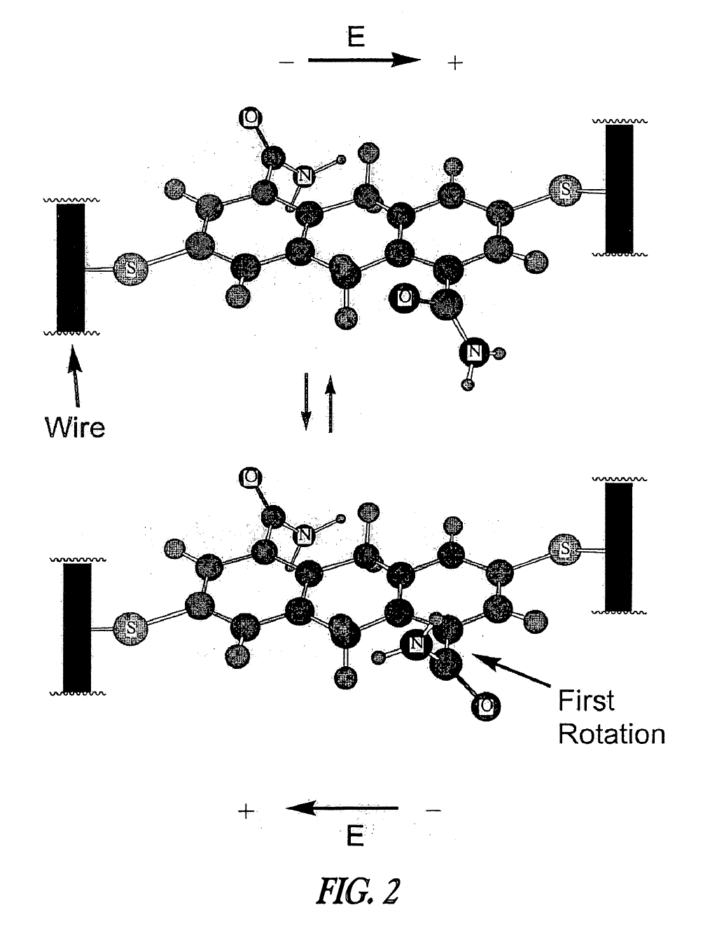

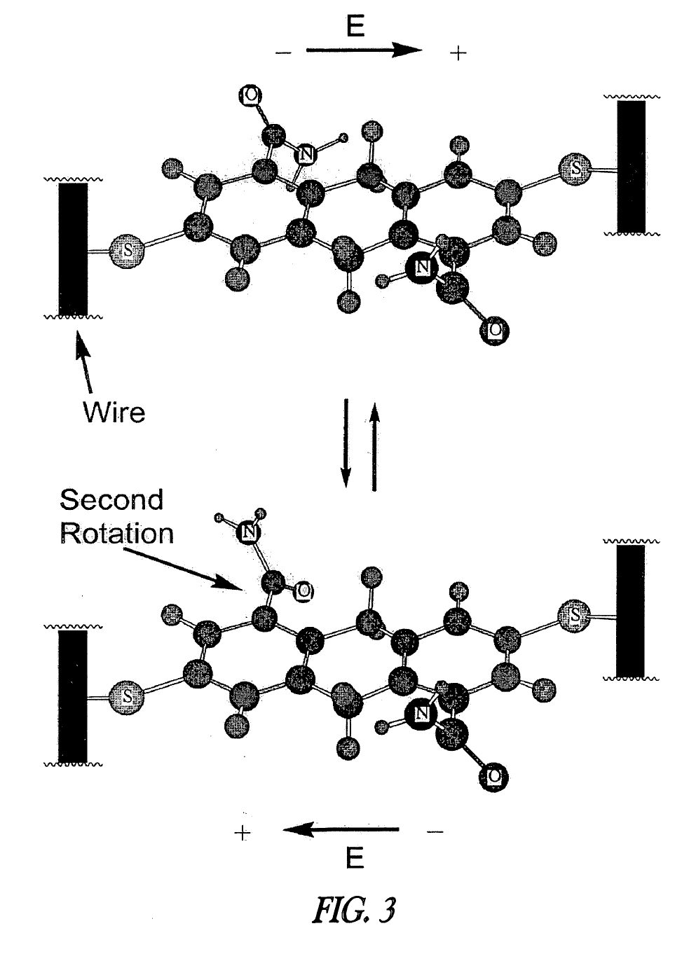

A specific multi-stable molecular junction is a compound of Formula II: 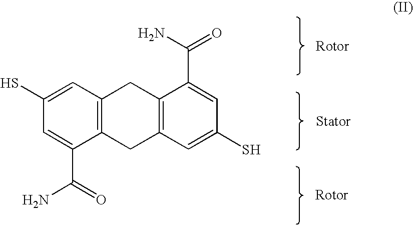
which is conceptually illustrated in FIGS. 2 and 3. The compound of FIGS. 2 and 3 is an example of a two rotor multi-stable molecule. Multi-stable molecules with three or more rotors attached can also be employed. The molecule is designed with a stator portion and two or more appended rotors, which are perpendicular to the orientation or current-carrying axis of the entire molecule; that is, from left to right or vice versa, as shown above. Compounds in of various embodiments will possess two or more rotors situated at any suitable and effective location on the stator portion of the molecule.

In FIGS. 2 and 3, the external field is applied along the longitudinal axis of the molecule (horizontal direction) as pictured—the electrodes (wires) are oriented in such a manner that their lengths cross each other, and the point of intersection is the junction molecule(s). Application of an electric field oriented from left to right in FIG. 2 will cause the right-hand rotor of the top molecule as pictured in FIG. 2 to rotate approximately 180° to the position shown at the bottom of FIG. 2. In other embodiments, a rotor will rotate any angle sufficient to switch the state of the molecule. A sufficient angle can be approximately 60°, approximately 120°, approximately 180°, or any other suitable angle for switching the state of the molecule. Application of the electric field from the right to left as shown at the bottom of FIG. 2 will cause the rotor to rotate from the position shown at the bottom of FIG. 2 to that shown at the top of FIG. 2. Switching from one stable state to the other stable state is reversible, but is not readily affected by thermal fluctuations. Many rotors will have a switching barrier of about 0.3 eV or more. Other rotors can have switching barriers anywhere in the range of about 0.1 eV to about 3.5 eV. Specific switching barriers include at least about 0.15 eV, at least about 1 eV, or at least about 3.5 eV.

FIG. 3 is a continuation of FIG. 2, wherein a stronger external field is applied across the multi-stable molecule to cause the second rotor (left-hand rotor as illustrated) to rotate to the position shown at the bottom of FIG. 3. Application of an electric field from the right to left as shown at the bottom of FIG. 3 will cause the rotor to align parallel to the external field by rotating from the position shown at the bottom of FIG. 3 to that shown at the top of FIG. 3.

Various embodiments utilize a new type of switching mechanism wherein an electric field induces the rotation of at least one of two or more molecular groups (rotors). Each rotor possesses a sufficiently large dipole moment that causes the rotor to rotate and align substantially parallel to an external field exerted on the molecule. The two or more rotors can be different from each other, such that three or more local energy minima can be obtained. The molecule is neither oxidized nor reduced during switching, thus a nonreversible reaction is avoided. The size of the rotor can be measured in nanometers, and as a result the switching time is fast, on the order of a picosecond. The molecules are typically simpler in structure than rotaxanes and rotaxane-related compounds. The molecules are thus easier and cheaper to make.

One embodiment uses molecules possessing rotors to form active electronic devices that can be switched with an external electric field, i.e., the rotor configurational state can be changed. Rotor-stator molecules can be synthesized such that a stationary portion (stator) bridges two electrodes. Each stator has two or more conformationally multi-stable groups (rotors) appended to it. Each rotor possess a relatively large electronic dipole moment. The molecule is designed such that intra-molecular forces, such as hydrogen bonding and steric interactions, stabilize the rotors asymmetrically with respect to the stator. The stators are stationary or substantially stationary in the device, and each multi-stable junction molecule is in contact with two electrodes.

The stator can be symmetric or asymmetric with respect to the rotation axis of each rotor. Each rotor has at least two stable orientations (local energy minima) and an energy barrier prevents rotation from one state (orientation) to the another (see FIGS. 2 and 3). The height of the barrier, in terms of activation energy, should be sufficiently larger than the energy provided by the operational temperature of the device so that the switch is not be activated by random thermal fluctuations. Under operational conditions, when a rotor is in one particular orientation, it will remain there and will not switch to the alternate stable state until switching is caused by an external electric field.

The rotors of the multi-stable molecules can be any moiety that has an intrinsic electronic dipole. The base atom of the rotor (the atom that is covalently bonded to the stator) can be carbon, as in Formulae I-III, or it can be an atom other than carbon, such as N, Si, P, S, or Se, as long at the rotor has an electronic dipole moment. The rotors can also be linked to the stator through a linker. The linker can be an organic group, such as an alkane, alkene, or alkyne group. The linkers can be used to avoid undesired steric or electronic interactions with nearby groups. In some embodiments, the rotors have two preferred alignments. In other embodiments, individual rotors can have more than two preferred alignments or rotor configurational states.

Switching can be achieved with an external field by applying a bias voltage between the two electrodes in electrical contact with the stator. The dipole moments of the rotors will attempt to align parallel to the external field exerted on the molecule when sufficient field energy is provided, subject to the constrains imposed by steric restrictions and intra-molecular bonding for the rotor and stator. If the initial direction of a rotor's dipole is opposite to that of the applied field, then the rotor will be forced to rotate with respect to the stator and switch to a second stable state at some threshold bias voltage. The second rotor will typically switch at a different threshold bias voltage, thus creating the potential for three or more different energy levels in an applied external field. The rotors will remain in their current stable states until an external field of sufficient magnitude is applied to achieve an overall more stable state or until an external field of sufficient magnitude is applied in the opposite direction, wherein the rotors will reverse to obtain a stable state, with the rotors in the opposite orientation. For information on field-switchable dipole groups, see Kornilovitch et al., Phys. Rev. B, 2002, 66, 245413.

The molecular devices of an embodiment comprises a molecule with multiple electronic states, which are determined by relative configurations of the rotors. Each type of junction molecule has discrete electronic properties that can be used for logic operations. Novel logic techniques, such as 4, 8, or higher state operations, may be performed, depending on the number of stable electronic states in the junction molecules. One embodiment makes use of molecules with multi-stable internal states, for which certain states have distinguishable electronic properties, such as conductance.

The electronic orbitals of a multi-stable molecule define its electronic state. The electronic state determines the transport properties of an electron traveling from one electrode to another. The electronic state is distinct from the molecular configurational (spatial or geometric) state. One can apply a distinct set of voltages or a patter of voltages through the electrodes to deliberately force a multi-state molecule into a desired molecular configurational state. The electronic state of the molecule refers to the energy level of the electrons, the position of their orbitals, and the wave functions of the molecules, which will determine their conductivity properties, while the molecular configurational state refers to its geometric orientation.

A particular set of low-energy rotor orientations with respect to the stator defines a molecular configuration state. For each molecular configuration state, there is a set of electron orbitals which define a molecular electronic state. The molecular electronic state defines the electronic transport properties across the molecule, between electrodes. Thus, a molecule can be set to a specific molecular configurational state (the sum of the configurations of the rotors) by applying certain specific voltages; the electronic state can then be read by applying a test voltage, which is normally much lower in magnitude than the voltage used to configure the junction molecule(s), and reading the resistance across the junction, which in turn indicates the molecular electronic state.

Multi-stable molecules in different molecular configurational states can display significant differential conductance and resistance. In some embodiments, devices include a plurality of multi-stable molecules at the junction of two electrodes. A sequence of appropriate positive and negative voltages can be applied to the electrodes to deliberately place the molecule in a known molecular configurational state. Accordingly, a new electronic state is achieved. Thus, the multi-stable molecules can be programmed into a desired electronic state by changing its molecular configurational state. Each molecular configurational state will have a characteristic conductance under a particular test voltage that can be used to measure changes in the rotor configurational states of the molecule and the device therefore can act as a memory device.

The multi-stable molecules can display hysteresis. For example, a positive voltage can be applied across a multi-stable molecule, which can cause a first rotor to rotate. By increasing the positive voltage, a second, third, and fourth, etc. rotor can be caused to rotate, one after another as the voltage is increased. The local environment and individual properties of each rotor determine what voltage will cause it to rotate. When an identical negative voltage is then applied in the opposite direction, the rotors do not always rotate back to their original positions in the same order. Thus, the device does not simply track the voltage applied to it.

A sufficiently large positive voltage will create a configuration with each rotor aligned with the direction of the positive voltage. A sufficiently large negative voltage will create an opposite molecular configuration. As the opposite voltage is applied, one rotor will eventually rotate to align with the newly applied field to produce a new electronic state. A rotor that rotated at a particular point in the sequence of rotor rotations for the first voltage will not always rotate back at that same point in the sequence when the opposite voltage is applied. For example, the third rotor to rotate under an applied positive voltage is not always the third rotor to rotate back when an equivalent negative voltage is applied. The display of this property is called hysteresis.

By applying a set of positive and/or negative voltages, one can, in principle, explore each discrete electronic state of the hysteresis curve of a multi-stable molecule or its device. By reading the conductance of a junction, one can determine the electronic state of a junction. By correlating molecular configurational states and electronic states, an energy profile of the multi-stable molecule at the junction can be obtained. The energy profile will allow for the determination of a set of rules for moving back and forth between various electronic states. This will allow for the design of a molecule such that a graph of the various configuration states can be produced. A map could be created for obtaining each state by a series of applied positive and negative voltages. In certain molecules, some states may not be obtainable by certain methods.

An example of a multi-stable molecule is a compound of Formula III: 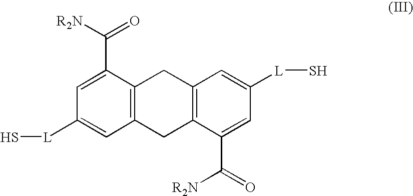
wherein each R is independently H, alkyl, cycloalkyl, aryl, heteroaryl, or heterocycle, and each L is independently (Yₘ—(CH₂)ₚ)_{q}—SH, wherein each Y is independently O, NH, or S, m is 0 or 1, p is 0-12, and q is 0-6. In some embodiments, q is 0, and in other embodiments, q is 1-6.

A specific example of a multi-stable molecule is a compound of Formula II:

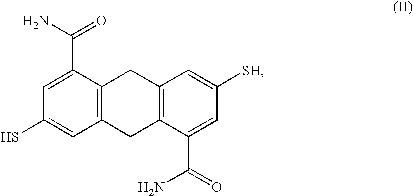

which is illustrated in FIGS. 2 and 3. Molecules of Formula II have a central static portion (stator) connected to two rotors, one on each side. The states of the molecule may be represented by the relative orientations of the dipoles: ↑↑;↓↓; ↑↓ and ↑↓. These four states have three different energies in an applied external electric field. The states ↑↓ and ↑↓ have the same energy, but they are different from ↑↑ and ↓↓, which have different energy from each other. Thus, a different field orientation and field strength can be used to set the three different energy states. Each state will have a different electrical conductivity. This differentiation forms the basis for making the primitives for logic operations, and can be used to create a truth table by setting a resistance threshold. For example, the following table can be an XOR gate, wherein if at least one rotor of a dipole is oriented in a selected orientation, a logic “1” results. When a rotor is in a different selected orientation, a logic “0” can result.

| | ↑ | ↓ |
|---|---|---|
| ↑ | 1 | 1 |
| ↓ | 1 | 0 |

A memory device can be prepared that stores more than a binary piece of information at one junction. For example, a junction molecule can store a 0, 1, 2, or 3, instead of simply a 0 or 1. Molecules with three or more rotors can store even larger sets of numbers. This function drastically increases the amount of data that can be stored in a given circuit area.

Two or more rotors and two or more connector groups can be situated at any suitable and effective position on the stator. The connector can be a thiol group or any other moiety that effectively contacts an electrode. The connection can be covalent, ionic, Van der Waals, or any other type of association that allows for the tunneling of electrons through the multi-stable molecule. One type of junction species for molecular devices can be created by placing the rotors on the same side of the molecule, for example, as in the following junction species: 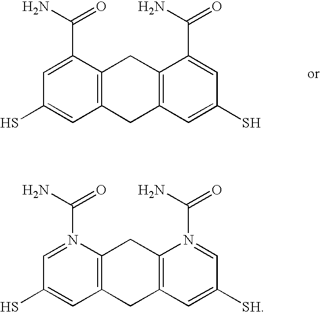
Again, the four electronic states obtainable from the above junctions species have different energies in an external field. The different conductivities of those states will define a new truth table. Adding more rotors to the stator molecule can increase the number of internal states, and thus enlarges the truth table for the molecules. These molecules can serve as the basis for computing logic.

Formula I below represents a switchable molecule with two or more active (switchable) dipole-possessing groups, kept in a stable configuration by steric interactions and/or hydrogen bonding to sites on the stator portion of the molecule: 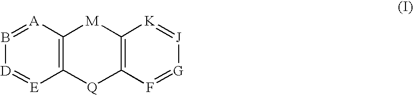
wherein

A, B, D, E, F, G, J, and K, are each independently C—X; C—H; C—R; C—N(R)(R′); N; C-halogen; C—OR; C—SR; C(═O)N(R)(R′); C(═O)OR; or C—(═O)SR;

M and Q are each independently C(R)(X); N—X; P(O)ₙX; boron-X; CH₂; CHR; CH(halogen); C(halogen)₂; CHOR; CO; —CH═CH—; —CH₂—CH₂—; C═C(R)(R′); S(O)ₙ; O; NR; or N—COR;

X is independently hydrogen or C(═Y)Z;

Y is independently O; NR; or S;

Z is independently R; N(R)(R′); OR; S(O)ₙR; CHR—NHR; CHR—OR; CHR—S(O)ₙR; CHR-halogen; NR—NHR; NR—OR; or NR—S(O)ₙR;

R and R′ are each independently H, alkyl, cycloalkyl, aryl, heteroaryl, or heterocycle; and

n is 0-2;

provided at least two of A, B, D, E, F, G, J, K, M, and Q are X, wherein X is independently C(═Y)Z; and

provided at least two of A, B, D, E, F, G, J, K, M, and Q are independently C—(Yₘ—(CH₂)ₚ)_{q}—SH,

wherein each Y is independently O, NH, or S;

m is 0 or 1;

p is 0-12; and

q is 0-2.

According to one embodiment, D and J can be C—SH, and in another embodiment, D and J can be C—O—(CH₂)₆—SH. Thiol containing groups can be located at any suitable and effective location on the molecule in order to form a junction.

A compound of Formula II illustrates a specific multi-stable molecule of an embodiment wherein the amide groups are the rotors and the thiol groups are the connectors that serve as means to bond, attach, or otherwise associate with electrodes of a molecular device: 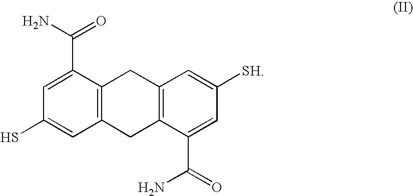
Some representative multi-stable compounds of Formula I that can serve as junctions or switch species are illustrated below, wherein at least two of the variable sites comprise a connector group. 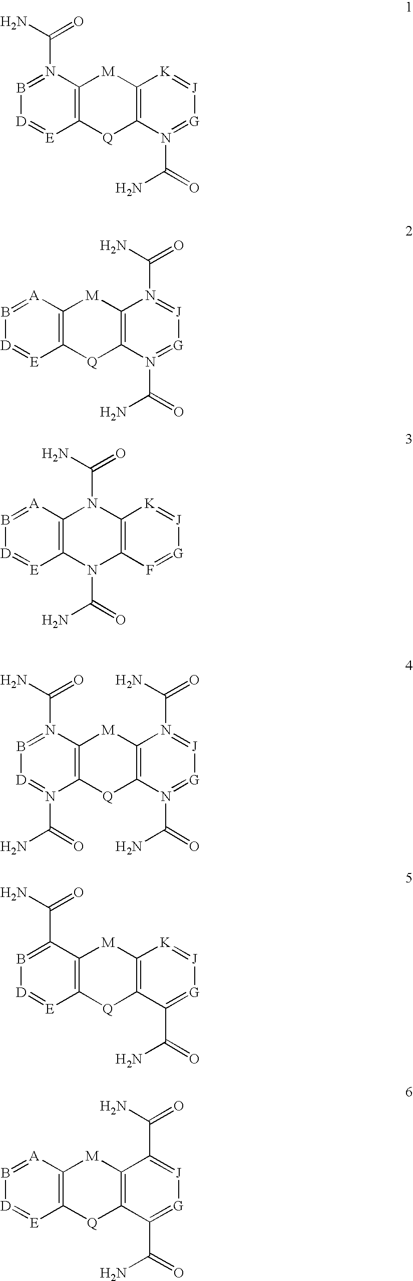 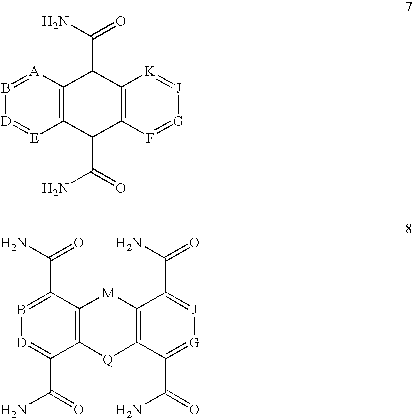
The multi-stable compounds of Formula I can be any molecule of Formula I with two or more rotors and two or more connector groups attached to the stator portion of the molecule. The junction molecules can preferably have rotors on different rings, such as in compounds 1 and 5. The variable groups M and Q can form a conjugated π-system with the outer rings, or preferably M and Q do not form a conjugated π-system with the outer rings.

The rotors are typically a group X, wherein X is C(═Y)Z. One example of a rotor is an amide group. Another example of a rotor is a substituted amide. The rotors of a particular stator can be the same. Alternatively, one or more rotors of a stator can be different from each other. In one embodiment, each rotor is different from every other rotor. Rotors of different atoms and sizes can require different external field strengths in order to switch states. One can tune the junction molecule by selection of an appropriate set of rotors, each of which switch at different applied electric fields.

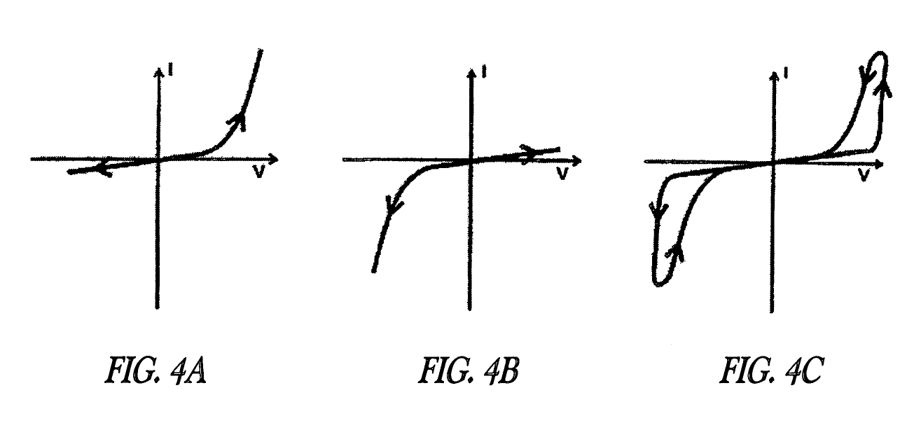

One component of the molecular design is that the asymmetric mutual orientation of a rotor and stator and their strong interaction will yield an asymmetric diode-like current-voltage (I-V) characteristic; see FIG. 4a, which depicts the I-V characteristic of a molecule when a rotor is in one stable orientation with respect to the stator.

The I-V characteristic will invert with respect to the applied voltage when the field across the molecule causes a rotor to reverse its orientation; see FIG. 4b, which depicts the I-V characteristic when a rotor is flipped to the second stable state.

The I-V characteristic of the multi-stable molecule will thus create a strong and symmetric hysteresis loop for the I-V characteristic of a pair of identical electrodes with molecules of this type trapped inside; see FIG. 4c, which depicts a full hysteresis loop. A distinct feature of the loop is that both its parts are traversed anti-clockwise (as in this example) or clockwise. These molecules can be used as the active medium in, for example, a cross-point memory or as a switching element.

Fabrication of Wire Electrodes

Nanowires of various metallic and semiconducting materials can be prepared by a variety of methods known to those of skill in the art. These wires can be used as electrode contacts to multi-stable molecules to produce an electronic switching, gating, or memory device. Process-defined wires are defined as wires that are prepared by electronic-circuit processing techniques. Process-defined wires can be prepared on a substrate as part of a circuit. Metallic and semiconductor wires, with diameters ranging from several micrometers to about a single micrometer (defined as micrometer-scale), or with diameters ranging from a single micrometer down to about 40 nanometers (defined as sub-micrometer scale) in diameter, can be prepared using methods employed by those of skill in the art, including, for example, optical-, ultraviolet-, or electron beam-lithography. The wires typically have a ribbon shape or rectangular cross section. Circular cross sections can also be prepared. The width of the wire can be determined by the lithographic process used to define the wire and its height can be defined by the amount of material deposited in the region defined by lithography.

Chemically-prepared wires are wires that are prepared by techniques other than conventional electronic processing technology. These wires are typically prepared as a bulk material, rather than as part of a circuit board. Metal and semiconductor nanowires are defined as wires with diameters below about 50 nanometers (typically about 2 to about 20 nanometers), and with lengths in the range of about 0.1 micrometers to about 50 micrometers (typically about 5 to about 10 micrometers). These may be prepared chemically using any one of a number of techniques known by those of skill in the art, some of which are described in the references cited hereinbelow.

An example of a technique for the production of semiconductor nanowires of the semiconducting element germanium is reacting germanium tetrachloride and phenyltrichlorogermanium with a dispersion of sodium metal in a solvent, such as toluene, at a temperature near 300° C. in a closed vessel, under an inert atmosphere, for a period of several days. The procedure can produce single-crystal germanium nanowires of diameters 3 to 30 nanometers, and of lengths from 0.5 to 10 micrometers.

Another example is a technique for the production of semiconductor nanowires of the semiconducting element silicon, wherein a target containing elemental silicon and iron is laser vaporized. The target is placed in a vacuum oven at 1300° C., and an inert gas is flowed through the oven during the vaporization process. The technique can produce silicon wires that have diameters in the range of 20 to 30 nanometers, and lengths ranging from 1 to 20 micrometers.

An example of a technique for the production of metallic nanowires of the metallic element gold is to electrochemically grow gold wires within the pores of an anodically etched aluminum oxide thin film. The aluminum oxide is dissolved in acidic solution, releasing the gold nanowires, which are then collected. Gold nanowires grown in this manner are characterized by diameters ranging from 20 to 30 nanometers, and lengths ranging from 0.5 to 5 micrometers.

Doped Wire Electrodes:

Semiconducting wires can optionally be doped with a suitable and effective semiconductor dopant. Examples of typical dopants include phosphorus and boron. Silicon wires can be doped when the wires are physically prepared. In some embodiments, the dopant can be added into the reaction vessel as the wires are formed. For example, in the laser ablation/vacuum oven preparation technique described above, a small amount of dopant gas, such as phosphorus trihydride (PH₃) or arsenic trihydride (AsH₃) is added to the inert gas (argon, for example) that is passed through the vacuum oven during the laser ablation/wire formation process.

Conversely, wires can be modulation-doped by coating their surfaces with appropriate compounds containing either electron-withdrawing groups (Lewis acids, such as boron trifluoride (BF₃)) or electron-donating groups (Lewis bases, such as alkylamines (NR₃)) to provide p-type or n-type conductors, respectively.

When silicon nanowires are exposed to air, a thin surface layer (typically about 1 nm) of silicon dioxide will naturally form. At the SiO₂/air interface, the SiO₂ surface is terminated by Si—O—H bonds. To dope the wires via modulation-doping, the surface of the wires can be chemically functionalized. Organic or inorganic molecules can be used to covalently bond to free Si—O—H groups at the surface of the wires. Groups that will bind to or replace Si—O—H groups include, for example, R—Si(CH₃)ₓ(OCH₃₋ₓ), R—Si(CH₃)ₓ(OCH₂ CH₃₋ₓ), R—Si(CH₃)ₓCl₃₋ₓ, as well as any other suitable and effective compound that can react with the free hydroxyl on the silicon dioxide surface. As used in this paragraph, the variable R can represent an organic or inorganic moiety that contains an electron-withdrawing (a Lewis acid) or electron-donating groups (a Lewis base). This chemistry of binding molecules to a SiO₂ passivated silicon surface is well established. One reaction for binding molecules to the surface of SiO₂ passivated silicon is:
Si—O—H_{(surface)}+R—Si(CH₃)₂Cl→Si—O—Si(CH₃)₂R+HCl

Other types of semiconductor wires can be functionalized with organo-amines, organo-thiols, organo-phosphates, etc. Such functionalization can be used to facilitate the formation of a bond, attraction, or association between the wires and molecular junction molecules to form an electronic device.

For other nanowires, such as metal nanowires, the wires can be chemically functionalized with R—SH (for, e.g., gold, silver, or nickel wires), or R—NH₂ (for, e.g., platinum wires or palladium wires), or R—CO₂H for other metals such as Al₂O₃-coated aluminum wires or titanium wires), where the R-group denotes an organic moiety, e.g., an alkyl, cycloalkyl, aryl, heteroaryl, or heterocycle, that will lend the wire certain chemical properties—such as the property that will allow a person skilled in the art to disperse the wires, e.g., as a colloid in a solvent. In one embodiment, gold wires can be functionalized with dodecanethiol (C₁₂H₂₅SH). The dodecanethiol provides a thin surface tunneling barrier, and will allow for the wires to be dispersed in simple organic solvents, such as hexane or chloroform. The solvent can also be removed to obtain solid devices after the addition of multi-stable molecules to the dispersion.

Wire preparation techniques are further discussed in the following citations, which are hereby incorporated by reference:

Silicon: A. M. Morales et al., “A laser ablation method for the synthesis of crystalline semiconductor nanowires”, Science, 1998, 279, 208-211.

Functionalized Silicon: T. Vossmeyer et al., “Combinatorial approaches toward patterning nanocrystals”, J AppL. Phys., 1998, 84, 3664-3670 (one of a number of useful references).

Germanium: J. R. Heath et al., “A liquid solution synthesis of single crystal germanium quantum wires”, Chem. Phys. Lett., 1993, 208, 263-268.

Functionalized Surfaces of Gold Nanostructures: D. V. Leff et al., “Thermodynamic Size Control of Au Nanocrystals: Experiment and Theory”, J Phys. Chem., 1995, 99, 7036-7041.

Metal Nanowires: V. P. Menon et al., “Fabrication and Evaluation of Nano-electrode Ensembles”, Anal. Chem., 1995, 67, 1920-1928.

A coating 20 on wire 12 and a coating 22 on wire 14 are illustrated in FIG. 1b. The coatings 20, 22 may be modulation-doping coatings, tunneling barriers (e.g., oxides), or other nano-scale functionally suitable materials. Alternatively, the wires 12, 14 themselves may be coated with one or more R species 16, and where the wires cross, Rₛ, 18 (e.g., junction molecules of Formula I) is formed. Also, the wires 12, 14 can be coated with molecular species 20, 22, respectively, for example, that enable one or both wires to be suspended to form colloidal suspensions, as discussed below. The connector species 18 comprises a material that displays a significant, or measurable, hysteresis in its current-voltage curve, as obtained either from solution electrochemistry or from current-voltage characteristics in a solid-state junction.

Synthesis of Multi-stable Molecules

A representative preparation of molecules having Formula I is described in the following section. One skilled in the art can prepare a variety of molecules of Formula I by changing and modifying the synthetic methods, or by using alternative synthetic methods well known to those of skill in the art.

Starting compounds IV and V can be combined via condensation-cyclization, followed by reduction to form an intermediate compound VI. Compounds IV and V are often commercially available and many representative compounds are described in, e.g., Aldrich Handbook of Fine Chemicals, 2003-2004 (Milwaukee, Wis.), or they can be prepared by methods known by those of skill in the art. Suitable transformations for the preparation of intermediates and compounds of formula I are found in, for example, Carey & Sundberg, Advanced Organic Chemistry, Parts I and II, 4th Eds., Plenum: 2001; Encyclopedia of Reagents for Organic Synthesis, Leo A. Paquette, Ed.-in-Chief, Wiley: 1995; Fieser and Fieser, Reagents for Organic Synthesis, Vol. 1-16, Wiley; March, J., Advanced Organic Chemistry, John Wiley & Sons, 4th ed.,1992; House, H. O., Modern Synthetic Reactions, 2d ed., W. A. Benjamin, New York, 1972; and Larock, R. C., Comprehensive Organic Transformations, 2nd ed., Wiley-VCH Publishers: New York, 1999.

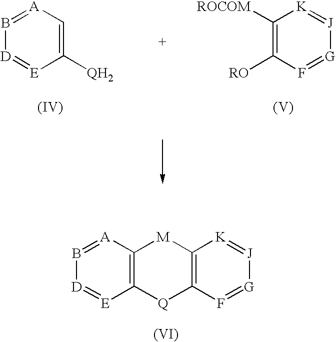

Intermediate VI is then reacted with Z(Y═)C-LG, wherein LG is a leaving group, under basic conditions to form Compound VII, as illustrated below.

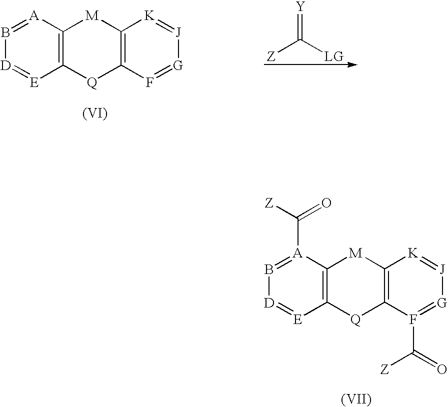

The starting materials employed in the synthetic methods described herein are commercially available, have been reported in the scientific literature, or can be prepared from readily available starting materials using procedures known in the field. It may be desirable to optionally use protecting groups during all or portions of the above described synthetic procedures. In certain embodiments, a compound can also include such protection groups when used in molecular devices. Protecting groups and methods for their introduction and removal are well known in the art. See Greene, T. W., Wutz, P. G. M. Protecting Groups In Organic Synthesis, 2 ed., John Wiley & Sons, Inc.: New York, 1991.

It will be appreciated by those skilled in the art that compounds having a chiral center may exist in and be isolated in optically active and racemic forms. Some compounds may exhibit polymorphism. It is to be understood that various embodiments disclosed herein encompasses any racemic, optically-active, polymorphic, or stereoisomeric form, or mixtures thereof, of a compound, which possess the useful properties described herein. It is well known in the art how to prepare optically active forms (for example, by resolution of the racemic form by recrystallization techniques, by synthesis from optically-active starting materials, by chiral synthesis, or by chromatographic separation using a chiral stationary phase).

It will also be appreciated by those skilled in the art that multi-stable compounds with one, two, or more than three rings can be prepared for use in some embodiments. In other embodiments, any suitable and effective stator can be used in conjunction with any suitable and effective rotors that have intrinsic dipole moments. The stator can be any molecular structure that is attached to two or more rotors, wherein each rotor has two or more discrete rotor configurational (geometric) energy minima. The stators can also be symmetrical or they can be asymmetrical.

Device Preparation

The representative molecules, illustrated by Formula (I), may be prepared by a variety of techniques and employed in microscale and nanoscale applications. For example, a single monolayer molecular film can be grown on an electrode or wire, for example using Langmuir-Blodgett techniques or self-assembled monolayer (also called SAMs), such that the orientation or current-carrying axis of the molecules is perpendicular to the plane of the electrodes used to switch the molecules. Bottom and top electrodes may be deposited in the manner described by Collier et al. (Science, 1999, 285, 391-394) and Chen et al. (Appl. Phys. Lett., 2003, 82, 1610-1612), or by methods described in, for example, U.S. Pat. Nos. 6,674,932; 6,624,002; 6,559,468; 6,459,095; 6,314,019; 6,256,767; 6,128,214; 5,903,010; and references cited therein, each of which are hereby incorporated by reference.

The wires can comprise any metal or compound that forms a bond or association with the connector group, or that is strongly attracted to the connector group on a molecular level. The thiol groups of Formula I can be used to connect the electrodes of a molecular device. See A. Ulman, Characterization of Organic Thin Films, Butterworth-Keinemann: Boston, 1995, for sulfur-metal bonding and interaction. The wires can comprise, for example, gold, platinum, titanium, silver, and/or nickel. The wires connected by the junction molecules can be the same or of a different metal or composition.

The technology disclosed and claimed herein for forming molecular devices may be used to perform a variety of functions and to form a variety of useful devices and circuits for implementing computing on a microscale and even on a nanoscale. For example, applications include molecular wire crossbar interconnects (MWCI) for signal routing and communications, molecular wire crossbar memory (U.S. Pat. No. 6,128,214), molecular wire crossbar logic (MWCL) employing programmable logic arrays, a demultiplexer for a molecular wire crossbar network, and molecular wire transistors.

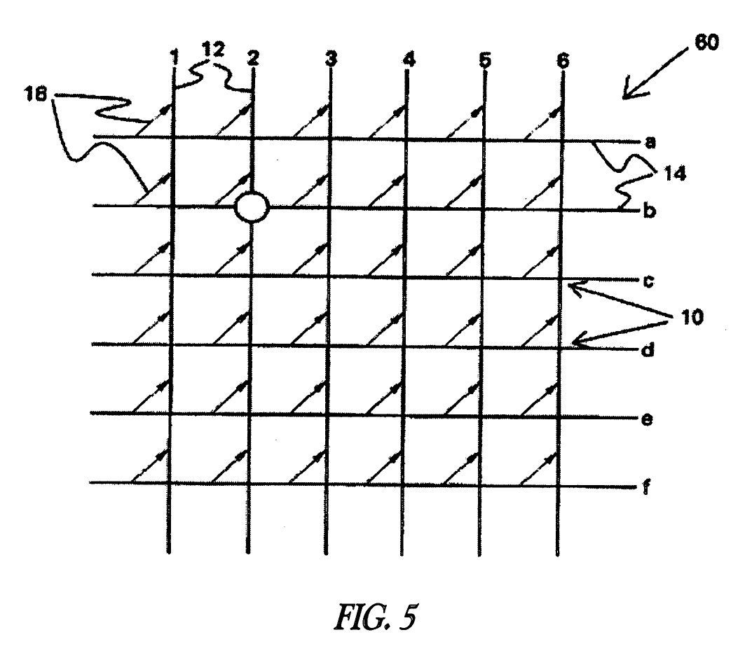

As illustrated in FIG. 5, the switch 10 of one embodiment can be replicated in a two-dimensional array to form a plurality, or array, 60 of switches to form a crossbar switch. FIG. 5 depicts a 6×6 array 60, but this embodiment is not so limited to the particular number of elements, or switches, in the array. Access to a single point, e.g., 2b, is done by impressing voltage on wires 2 and b to cause a change in the state of the molecular species 18 at the junction thereof, as described above. Thus, access to each junction is readily available for configuring only those pre-selected junctions in accordance with the teachings herein. Details of the operation of the crossbar switch array 60 are further discussed in above-referenced U.S. Pat. No. 6,128,214.

In a device that employs multi-stable molecules, the stator portion of the multi-stable molecules are typically stationary with respect to the rotors and the electrodes in contact with the stators.

### INDUSTRIAL APPLICABILITY

The electrical function of these devices are largely determined by the types of wires (electrodes) and the interwire materials that are used. The wires can be composed of various types of metals, semiconductor (SC) materials, and doped variations thereof.

Depending on the molecules that are used between the wires (electrodes), the junction can have a switching function that changes the electrical conductance (among multiple electronic states) between the two wires. The switch will be reconfigurable. Electrically biasing the switch beyond a particular threshold voltage that is determined by the material of the junction, forces a dipole-containing rotor to rotate and adapt a different conformation, resulting in a different electrical conductivity. By cycling the polarity and magnitude of the voltage on the switch beyond the appropriate threshold values, it is possible to reversibly switch (rotate the rotors of) properly selected molecules to a particular state many times. In any case, the type of electrical connection that is made between the wires depends upon the materials from which the wires (or electrodes) are fabricated, as well as the identity of the molecules or materials between the wires. Thus, various embodiments can be executed with any number of metallic or semiconducting wire/molecule combinations, depending on the device properties desired from the assembled circuit.

The multi-stable molecules and molecular devices disclosed herein are expected to find use in micro-scale and nano-scale devices. In one embodiment, a molecule can be designed to have an appropriate hysteresis among molecular configurational states, so that depending on what sequence of positive and negative transitions are applied to it, the junction molecule will be set to specific rotor configurational states such that when measured, the electronic state associated with a specific molecular configurational state can be the answer to a computation.

In one embodiment, a multi-stable molecule can have one specific molecular configurational state that has a conductance significantly higher that all other molecular configurational states of that molecule. A multi-stable molecule can be designed such that a certain set of orientations of the rotors produce an overall energy level that is substantially aligned with the Fermi level, and thus that state has significantly higher conductance.

In one embodiment, a sequence of voltages of various magnitudes can be applied by the programming electrodes to create electric fields. Such a sequence of electric fields is the input to the finite state machine, and the measurement of current, defined by the electronic state of the molecule, is the output of the finite state machine.

Any publication, text, treatise, patent, or patent application disclosed herein is incorporated by reference into this disclosure and forms part of the disclosure. The invention has been described with reference to various specific embodiments and techniques, however it should be understood that many variations and modifications may be made while remaining within the spirit and scope of the invention.

What is claimed is:

1. A finite state machine comprising a plurality of multi-stable rotor-stator molecules;
wherein one or more multi-stable molecules has two or more rotors on a stator, each of said rotors independently has an electric dipole moment and multiple rotor configurational states; and
at least one stator is in electrical contact between two electrodes to form a junction.

2. The finite state machine of claim 1 wherein the multi-stable molecule is designed to have an hysteresis among molecular configurational states,
wherein a sequence of distinct electric fields set specific rotor configurational states such that when measured, a conductance of an electronic state associated with the specific molecular configurational state is the answer to a computation.

3. The finite state machine of claim 1 wherein the two or more rotors each independently have at least one energetic barrier to rotation which is greater than the thermal energy at the operating temperature of the finite state machine.

4. The finite state machine of claim 3 wherein energetic barrier to rotation comprises hydrogen bonding, Van der Waals forces, or steric interactions.

5. The finite state machine of claim 1 wherein the electrodes apply an electric field substantially along the longitudinal axis of one or more multi-stable molecules.

6. The finite state machine of claim 1 wherein the molecular configurational state of a multi-state molecule can be ascertained by applying an electrical current to the electrodes and measuring conductance or resistance.

7. The finite state machine of claim 1 wherein the molecular configurational state of the multi-state molecules can be changed by applying an electric field to the multi-state molecules through programming electrodes that are in physical contact with said multi-state molecules.

8. The finite state machine of claim 1 wherein the molecular configurational state of the multi-state molecules can be changed by applying an electric field to the multi-state molecules through programming electrodes that are in electrical contact with said multi-state molecules.

9. The finite state machine of claim 1 that is operable as a memory device to store information in higher than binary fashion.

10. The finite state machine of claim 1 wherein the multiple discrete rotor configurational states are binary.

11. The finite state machine of claim 1 wherein the multi-stable molecules are designed to provide a desired truth table and is therefore part of a logic device.

12. The finite state machine of claim 1 wherein the two or more rotors are independently C(═Y)Z;
wherein Y is independently O; NR; or S;
Z is independently R; N(R)(R′); OR; S(O)ₙR wherein n is 0, 1, or 2; CHR—NHR; CHR—OR; CHR—S(O)ₙR; CHR-halogen; NR—NHR; NR—OR; or NR—S(O)ₙR; and
R and R′ are each independently H, alkyl, thioalkyl, cycloalkyl, aryl, heteroaryl, or heterocycle.

13. A compound of formula I: 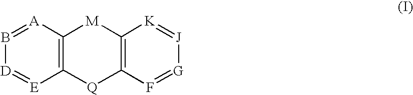
wherein
A, B, D, E, F, G, J, and K, are each independently C—X; C—H; C—R; C—N(R)(R′); N; C-halogen; C—OR; C—SR; C(═O)N(R)(R′); C(═O)OR; or C—(═O)SR;
M and Q are each independently C(R)(X); N—X; P(O)ₙX; boron-X; CH₂; CHR; CH(halogen); C(halogen)₂; CHOR; CO; —CH═CH—; —CH₂—CH₂—; C═C(R)(R′); S(O)ₙ; O; NR; or N—COR;
X is independently hydrogen or C(═Y)Z;
Y is independently O; NR; or S;
Z is independently R; N(R)(R′); OR; S(O)ₙR; CHR—NHR; CHR—OR; CHR—S(O)ₙR; CHR-halogen; NR—NHR; NR—OR; or NR—S(O)ₙR;
R and R′ are each independently H, alkyl, thioalkyl, cycloalkyl, aryl, heteroaryl, or heterocycle; and
n is 0-2; provided at least two of A, B, D, E, F, G, J, K, M, and Q are X,
wherein X is independently C(═Y)Z; and provided at least two of A, B, D, E, F, G, J, K, M, and Q are
independently C—(Yₘ—(CH₂)ₚ)_{q}—SH,
wherein each Y is independently O, NH, or S;
m is 0 or 1;
p is 0-12; and
q is 0-2.

14. The compound of claim 13 wherein B, E, G, and K are hydrogen; M and Q are CH₂, O, or NR; D and J are C—SH, or C—O—(CH₂)₆—SH.

15. The compound of claim 13 wherein at least one of A and F;, E and K; A and Q; E and M; A and K; A and M; M and K; E and F; E and Q; and Q and F; are both C—X.

16. The compound of claim 13 wherein A and F are C—X, and X is C(═O)NH₂.

17. The compound of claim 13 wherein each X is the same.

18. The compound of claim 13 wherein at least one X is not the same as another X.

19. The compound of claim 13 wherein the compound has the formula II:

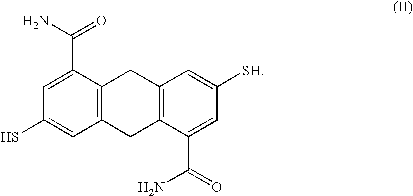

20. A method of fabricating a molecular device comprising a pair of electrodes which form a junction where one electrode crosses another and at least one connector species connecting said pair of electrodes in said junction, said junction having a functional dimension in nanometers, said method comprising:
(a) forming said first electrode,
(b) depositing said at least one connector species over at least a portion of said first electrode, and
(c) forming said second electrode over said first electrode so as to form said junction, wherein at least one connector species comprises a multi-stable molecule with two or more rotors.

21. The method of claim 20 wherein at least 0.15 eV is required to rotate a rotor.

22. The method of claim 20 wherein each electrode independently comprises a conductor or a semiconductor, and the junction forms a resistor or a diode.

23. The method of claim 20 further comprising an insulating layer or a modulation-doped layer on at least one wire.

24. The method of claim 20 wherein the molecular configurational state of the multi-stable molecule is ascertained by measuring its conductance.

25. A method of operating a molecular device comprising a pair of electrodes which form a junction where one electrode crosses another and at least one connector species connecting said pair of electrodes in said junction, said junction having a functional dimension in nanometers, said method comprising biasing both electrodes at least once with a first voltage sufficient to cause said connector species to switch its state, wherein at least one connector species comprises a multi-stable molecule, wherein the multi-stable molecule is a compound of claim 13.

26. A molecular device comprising a pair of electrode that form a junction where one electrode crosses another and at least one connector species connecting said pair of electrodes in said junction, said junction having a functional dimension in nanometers, wherein at least one connector species comprises a multi-stable molecule, wherein the multi-stable molecule is a compound of claim 13.
